(19) United States
(12) Patent Application Publication
(10) Pub. No.: US 2007/0298620 A1
(43) Pub. Date: Dec. 27, 2007

(54) SURFACE TREATMENT, SORTING AND ASSEMBLING METHODS OF MICROELECTRONIC DEVICES AND STORAGE STRUCTURE THEREOF

(76) Inventors: Kuang-Yeh Chang, Hsinchu (TW); Jin Yu, Singapore (SG)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,142

(22) Filed: Jun. 27, 2006

(51) Int. Cl. H01L 21/31

(52) U.S. Cl. 438/758

(57) ABSTRACT

A storage structure for a microelectronic device including a chip which has completed all back-end-of-line (BEOL) processes and a solvent dissolvable polymer layer covering the surface of the chip. Since the surface of the chip is isolated from the external environment by the solvent dissolvable polymer layer, corrosion, discoloring or delamination of the chip can be avoided.

### BACKGROUND OF THE INVENTION

1. Field of the Invention

The present invention relates to the treatments of a microelectronic device, and more particularly to the surface treatment, sorting and assembling of the microelectronic device and its storage structure thereof.

2. Description of the Related Art

Prior to final assembly and, during the period of storage, microelectronic device is often affected by the external environment. For example, after a long period of storage, corrosion, discoloration and delamination often appeared on the chip surface of the microelectronic device. Eventually, the finished product may contain some broken fragments.

### SUMMARY OF THE INVENTION

Accordingly, the objective of the present invention is to provide a surface treatment of a microelectronic device capable of protecting the chip surface of the microelectronic device against unfavorable environmental factors without incurring complicated and high-cost process.

Another objective of the present invention is to provide a wafer sorting method of microelectronic device capable of preventing the contamination of the chip surface without affecting the testing accuracy and the probe pin cleanliness.

Yet another objective of the present invention is to provide an assembling method of a microelectronic device capable of maintaining chip surface cleanliness without affecting the bonding operation and product quality.

Other objective of the present invention is to provide a storage structure for a microelectronic device capable of preventing the corrosion, discoloration or delamination of the chip surface during the storage period.

The present invention provides a surface treatment of a microelectronic device which suitable for a chip which has completed all back-end-of-line (BEOL) processes. This treatment includes forming a solvent dissolvable polymer layer on the surface of the aforementioned chip, so as to isolate the surface of the chip which has completed all BEOL processes from the external environment.

In the first embodiment of the present invention, the solvent dissolvable polymer layer can be fabricated using hexamethyidisilazane (HMDS), bis(dimethylamino)dimethylailane (BDMAS), dimethylsilyidiethylamine (DMSEDA) or other suitable polymers. Furthermore, the solvent dissolvable polymer layer is formed at a temperature between 90° C. and 120° C. with a processing time from 30 sec to 90 sec.

In the first embodiment of the present invention, the method of forming the solvent dissolvable polymer layer over the chip surface includes performing a physical vapor deposition process.

In the first embodiment of the present invention, a dehydration operation is performed prior to forming the solvent dissolvable polymer layer over the chip surface.

The present invention also provides a wafer sorting method of a microelectronic device. The method includes providing a chip, and then the chip undergoes the foregoing surface treatment so that a water-resistant layer is formed on the surface of the chip. The water-resistant layer is fabricated using a polymer material that can be dissolved in a solvent. Thereafter, a testing operation is carried out using probe pin to penetrate through the water-resistant layer.

The present invention also provides an assembling method of a microelectronic device. The method includes providing a chip and a circuit substrate. Then, the chip undergoes the foregoing surface treatment to form a water-resistant layer over the surface of the chip, wherein the water-resistant layer is fabricated using a polymer material that can be dissolved in a solvent. Thereafter, the water-resistant layer is removed before carrying out the bonding operation to join the chip and the circuit substrate together.

In the third embodiment of the present invention, the step of removing the water-resistant layer may further include simultaneously cleaning the surface of the chip. The cleaning operation includes applying a cleaning agent such as isopropyl alcohol (IPA) or DI water ultrasonic cleaning with hydrogen peroxide, ammonia water or diluted hydrofluoric acid (DHF) solution.

In the third embodiment of the present invention, the step of removing the water-resistant layer includes rinsing with a strong alkaline solvent, rinsing with a wet stripper or etching with plasma.

In the third embodiment of the present invention, after removing the water-resistant layer, further includes back-grinding of the chip.

In various embodiments of the present invention, the method of forming the water-resistant layer includes performing a physical vapor deposition process or some other suitable processes.

In various embodiments of the present invention, the water-resistant layer is fabricated using hexamethyidisilazane (HMDS), bis(dimethylamino)dimethylailane (BDMAS), dimethylsilyidiethylamine (DMSEDA) or other suitable polymers.

In various embodiments of the present invention, before forming the water-resistant layer, further includes performing a chip dehydration operation.

The present invention also provides a storage structure for a microelectronic device. The storage structure includes a chip which has completed all back-end-of-line processes and a solvent dissolvable polymer layer covering the surface of the chip to isolate the chip surface against the external environment.

According to the aforementioned storage structure in the present invention, the solvent dissolvable polymer layer can be fabricated using hexamethyidisilazane (HMDS), bis(dimethylamino)dimethylailane (BDMAS), dimethylsilyidiethylamine (DMSEDA) or other suitable polymers. Furthermore, the solvent dissolvable polymer layer has a thickness between several angstroms to several tens of angstroms.

In the present invention, a solvent dissolvable polymer layer is formed on the chip surface after completing all the back-end-on-line (BEOL) processes. Therefore, the surface of the chip will not be adversely affected by the external environment so as to cause surface corrosion, discoloration or delamination. Furthermore, the method of forming the solvent dissolvable polymer layer is simple to fabricate and has a low production cost. Moreover, the fabrication process is compatible to most back-end-on-line (BEOL) processes as well as clean room facility and processing stations. In addition, the present invention can also be used to sort microelectronic devices without affecting their testing accuracy and probe pin cleanliness. Further, the present invention can be used to assemble microelectronic devices without affecting their bonding operation or their product quality.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1B are schematic cross-sectional views showing the steps for performing a surface treatment of a microelectronic device according to the first embodiment of the present invention.

FIG. 2 is a flow diagram showing the steps for sorting microelectronic devices according to the second embodiment of the present invention.

FIG. 3 is a flow diagram showing the steps for assembling microelectronic devices according to the third embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

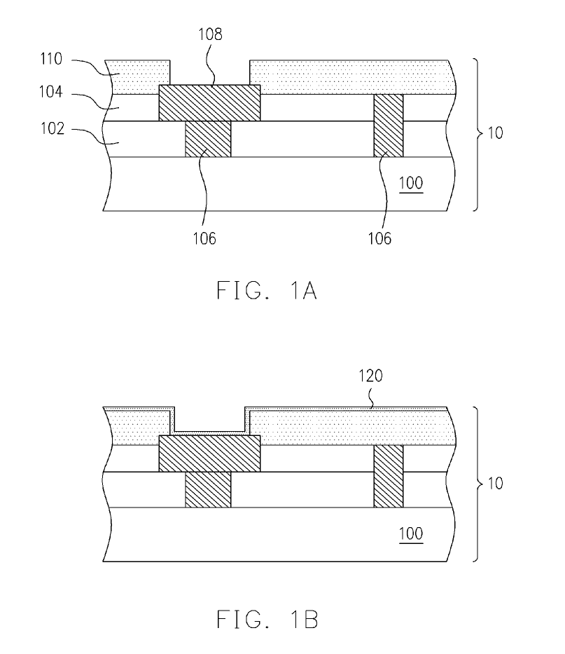

FIGS. 1A to 1B are schematic cross-sectional views showing the steps for performing a surface treatment of a microelectronic device according to the first embodiment of the present invention. As shown in FIG. 1A, the present invention provides a surface treatment for a microelectronic device suitable for performing on chip 10 which has completed all back-end-on-line processes. The chip 10 comprises a substrate 100, a plurality of dielectric layers 102, 104, 110, a plurality of via plugs 106 and a bonding pad 108, for example. The exposed layers on the chip 10 include the bonding pad 108 and the outermost dielectric layer 110. The foregoing structure of the chip 10 is just an example and should by no means limit the scope of the present invention as such.

As shown in FIG. 1B, the method in this embodiment includes forming a solvent dissolvable polymer layer 120 over the surface of the chip 10. The thickness of the solvent dissolvable polymer layer 120 is, for example, between several angstroms to several tens of angstroms. The process of forming the solvent dissolvable polymer layer 120 over the chip 10 is, for example, the physical vapor deposition (PVD) process.

Preferably, the solvent dissolvable polymer layer 120 has good adhesion to metallic material (for example, the bonding pad 108) and dielectric material (for example, the dielectric layer 110). In the present embodiment, the solvent dissolvable polymer layer 120 can be fabricated using hexamethyidisilazane (HMDS), bis(dimethylamino)dimethylailane (BDMAS), dimethylsilyidiethylamine (DMSEDA) or other suitable polymers. For example, the solvent dissolvable polymer layer 120 is formed at a temperature from 90° C. and 120° C. with a processing time from 30 sec to 90 sec. In addition, a dehydration operation can be performed before forming the solvent dissolvable polymer layer 120 over the surface of the chip 10.

After forming the solvent dissolvable polymer layer over the surface of a chip with all back-end-on-line (BEOL) processes completed, a storage structure for the microelectronic device according to the present invention is obtained. Due to the presence of the solvent dissolvable polymer layer, the microelectronic device is shielded from environmental contaminants.

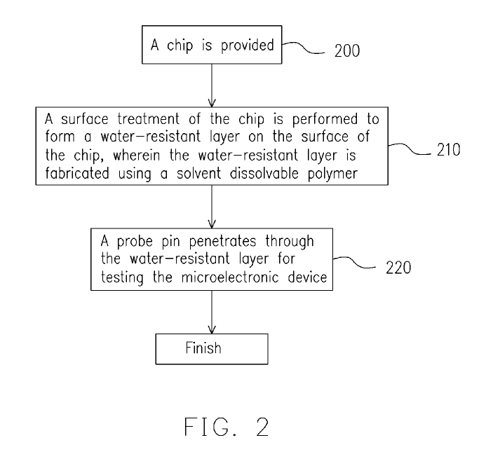

FIG. 2 is a flow diagram showing the steps for sorting microelectronic devices according to the second embodiment of the present invention. As shown in FIG. 2, a chip is provided in step 200. Furthermore, the chip can be dehydrated before executing step 210. Then, in step 210, a surface treatment of the chip as in the first embodiment is performed to form a water-resistant layer on the surface of the chip. The water-resistant layer is fabricated using a solvent dissolvable polymer such as hexamethyidisilazane (HMDS), bis(dimethylamino)dimethylailane (BDMAS), dimethylsilyidiethylamine (DMSEDA) or other suitable polymers. The method of forming the water-resistant layer is, for example, the physical vapor deposition (PVD) process or other suitable processes. Afterwards, in step 220, a probe pin penetrates through the water-resistant layer for testing the microelectronic device.

The water-resistant layer in the second embodiment will neither affect the testing accuracy in the sorting process nor contaminate the probe pin which performing the test, therefore it is compatible to the testing operation in wafer sorting.

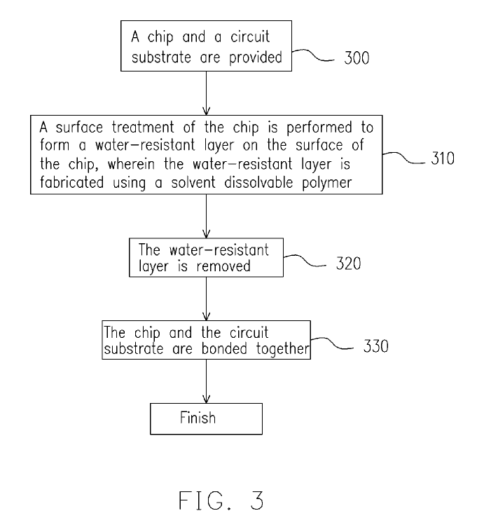

FIG. 3 is a flow diagram showing the steps for assembling microelectronic devices according to the third embodiment of the present invention. As shown in FIG. 3, a chip and a circuit substrate are provided in step 300. The chip can be dehydrated before carrying out the step 310 or the step 310 can be directly performed. In step 310, a surface treatment of the chip as in the first embodiment is performed to form a water-resistant layer on the surface of the chip. The water-resistant layer is fabricated using a solvent dissolvable polymer such as hexamethyidisilazane (HMDS), bis(dimethylamino)dimethylailane (BDMAS), dimethylsilyidiethylamine (DMSEDA) or other suitable polymers. The method of forming the water-resistant layer includes performing a physical vapor deposition (PVD) process or other suitable processes.

Thereafter, the water-resistant layer is removed in step 320. The method of removing the water-resistant layer includes performing a strong alkaline solvent cleaning as in the front-end-of line (FEOL) process, a wet stripper cleaning as in the back-end-of-line (BEOL) process or a plasma etching. In addition, the surface of the chip can also be simultaneously cleaned in the step 320. For example, the cleaning operation may include applying a cleaning agent such as isopropyl alcohol (IPA) or DI water ultrasonic cleaning with hydrogen peroxide, ammonia water or diluted hydrofluoric acid (DHF) solution (for example, the concentration of diluted hydrofluoric acid ≦100:1). An additional back grinding of the chip may also be carried out depending on the actual requirement. Finally, in step 330, the step of bonding of the chip and the circuit substrate together is performed.

In summary, one special aspect of the present invention is the formation of a solvent dissolvable polymer layer over the chip after completing all back-end-on-line processes. Thus, the surface of the chip is shielded from the damaging effects caused by the environment so that problem such as corrosion, discoloration or delamination on the surface of the chip is largely avoided. Moreover, the solvent dissolvable polymer layer is easy to produce and compatible with most BEOL processes as well as clean room facility and processing stations. The present invention can be applied to the sorting of microelectronic devices without affecting their testing accuracy and probe pin cleanliness. Furthermore, the present invention can also be applied to assemble microelectronic devices without affecting their bonding operation and quality.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A surface treatment method of a microelectronic device suitable for a chip which has completed all back-end-of-line (BEOL) processes, comprising the steps of:
forming a solvent dissolvable polymer layer over the surface of the chip, to isolate the surface of the chip which has completed all the back-end-of-line processes from the external environment.

2. The surface treatment method of claim 1, wherein the solvent dissolvable polymer layer is fabricated using hexamethyidisilazane (HMDS), bis(dimethylamino)dimethylailane (BDMAS) or dimethylsilyidiethylamine (DMSEDA).

3. The surface treatment method of claim 2, wherein the solvent dissolvable polymer layer is formed at a temperature from 90° C. to 120° C. with a processing time from 30 seconds to 90 seconds.

4. The surface treatment method of claim 1, wherein the step of forming the solvent dissolvable polymer layer on the surface of the chip comprises performing a physical vapor deposition process.

5. The surface treatment method of claim 1, wherein before forming the solvent dissolvable polymer layer over the surface of the chip, further comprises performing a dehydration operation.

6. A sorting method of microelectronic devices, comprising the steps of:
providing a chip;
performing a surface treatment of the chip according to claim 1 to form a water-resistant layer on the surface of the chip, wherein the water-resistant layer is fabricated using a solvent dissolvable polymer; and
performing a testing operation using a probe pin that penetrates through the water-resistant layer.

7. The sorting method of claim 6, wherein the step of forming the water-resistant layer comprises performing a physical vapor deposition process.

8. The sorting method of claim 6, wherein the water-resistant layer is fabricated using hexamethyidisilazane (HMDS), bis(dimethylamino)dimethylailane (BDMAS) or dimethylsilyidiethylamine (DMSEDA).

9. The sorting method of claim 6, wherein before forming the water-resistant layer, further comprises performing a dehydration operation.

10. An assembling method of microelectronic devices, comprising the steps of:
providing a chip and a circuit substrate;
performing a surface treatment of the chip according to the foregoing claim 1 to form a water-resistant layer on the surface of the chip, wherein the water-resistant layer is fabricated using a solvent dissolvable polymer;
removing the water-resistant layer before performing a bonding process; and
bonding the chip and the circuit substrate together.

11. The assembling method of claim 10, wherein the step of forming the water-resistant layer comprises performing a physical vapor deposition process.

12. The assembling method of claim 10, wherein the step of removing the water-resistant layer comprises simultaneously cleaning the surface of the chip.

13. The assembling method of claim 12, wherein the step of removing the water-resistant layer comprises cleaning using isopropyl alcohol as the cleaning solvent or DI water ultrasonic cleaning with hydrogen peroxide, ammonia water or diluted hydrofluoric acid solution.

14. The assembling method of claim 10, wherein the step of removing the water-resistant layer comprises cleaning with a strong alkaline solvent, cleaning with a wet stripper or etching with plasma.

15. The assembling method of claim 10, wherein the water-resistant layer is fabricated using hexamethyidisilazane (HMDS), bis(dimethylamino)dimethylailane (BDMAS) or dimethylsilyidiethylamine (DMSEDA).

16. The assembling method of claim 10, wherein after removing the water-resistant layer, further comprises back grinding of the chip.

17. The assembling method of claim 10, wherein before forming the water-resistant layer, further comprises performing a dehydration operation.

18. A storage structure for a microelectronic device, comprising:
a chip having completed all back-end-of-line processes; and
a solvent dissolvable polymer layer covering a surface of the chip to isolate the surface of the chip from the external environment.

19. The storage structure of claim 18, wherein the solvent dissolvable polymer layer is fabricated using hexamethyidisilazane (HMDS), bis(dimethylamino)dimethylailane (BDMAS) or dimethylsilyidiethylamine (DMSEDA).

20. The storage structure of claim 18, wherein the solvent dissolvable polymer layer has a thickness between several angstroms to several tens of angstroms.
